(19) United States
(12) Patent Application Publication
(10) Pub. No.: US 2017/0194529 A1
(43) Pub. Date: Jul. 6, 2017

(54) NITRIDE BASED LIGHT EMITTING SEMICONDUCTOR DEVICE WITH DESIRABLE CARBON TO ALUMINUM CONCENTRATION RATIO

(71) Applicant: PlayNitride Inc., Tainan City (TW)

(72) Inventors: Shen-Jie Wang, Tainan City (TW); Yun-Li Li, Tainan City (TW); Ching-Liang Lin, Tainan City (TW)

(21) Appl. No.: 15/174,790

(22) Filed: Jun. 6, 2016

(30) Foreign Application Priority Data
Jan. 4, 2016 (TW) 105100093

(51) Int. Cl. H01L 33/02; H01L 33/00; H01L 33/14; H01L 33/32; H01L 33/06; H01L 33/12

(52) U.S. Cl. CPC H01L 33/025; H01L 33/06; H01L 33/12; H01L 33/145; H01L 33/32; H01L 33/007

(57) ABSTRACT

A semiconductor light-emitting device including at least one n-type semiconductor layer, at least one p-type semiconductor layer, and a light-emitting layer is provided. The light-emitting layer is disposed between the at least one p-type semiconductor layer and the at least one n-type semiconductor layer. A ratio of carbon concentration to aluminum concentration in any one semiconductor layer containing aluminum in the semiconductor light-emitting device ranges from 10⁻⁴ to 10⁻².

### CROSS-REFERENCE TO RELATED APPLICATION

This application claims the priority benefit of Taiwan application serial no. 105100093, filed on Jan. 4, 2016. The entirety of the above-mentioned patent application is hereby incorporated by reference herein and made a part of this specification.

### BACKGROUND OF THE INVENTION

Field of the Invention

The invention relates to a light-emitting device, and particularly relates to a semiconductor light-emitting device.

Description of Related Art

With the evolution of photovoltaic technology, traditional incandescent bulbs and fluorescent lamp tubes have gradually been substituted with a new generation of solid state light source such as a light-emitting diode (LED), which has advantages such as long life, small volume, high shock resistance, high light efficiency, and low power consumption, etc. Thus, it has been used as a light source for use in household lighting and various devices. In addition to backlight modules of liquid crystal displays and household lighting lamps have widely adopted the light-emitting diode as a light source, the application field of the light-emitting diode has been expanded to road lighting, large outdoor billboards, traffic signal lights, UV curing, and related fields in recent years. The light-emitting diode has become one of the major developmental projects of the light source having both functions of electric power saving and environmental protection.

In a manufacturing process of epitaxy of general blue light or UV light light-emitting diode chips, carbon impurities are easily produced in semiconductor layers. However, the semiconductor layers having too high carbon concentration is easy to absorb UV light, thereby influencing light-emitting efficiency of UV light.

### SUMMARY OF THE INVENTION

The invention provides a semiconductor light-emitting device having a desirable ratio of carbon concentration to aluminum concentration.

A semiconductor light-emitting device of an embodiment of the invention includes at least one n-type semiconductor layer, at least one p-type semiconductor layer, and a light-emitting layer is provided. The light-emitting layer is disposed between the at least one p-type semiconductor layer and the at least one n-type semiconductor layer. A ratio of carbon concentration to aluminum concentration in any one semiconductor layer containing aluminum in the semiconductor light-emitting device ranges from 10⁻⁴ to 10⁻².

In an embodiment of the invention, each semiconductor layer in the semiconductor light-emitting device contains aluminum.

In an embodiment of the invention, aluminum concentration in the each semiconductor layer ranges from 5×10¹⁹ atoms/cm³ to 5×10²⁰ atoms/cm³.

In an embodiment of the invention, carbon concentration is less than hydrogen concentration in the at least one p-type semiconductor layer.

In an embodiment of the invention, carbon concentration is less than oxygen concentration in the at least one p-type semiconductor layer.

In an embodiment of the invention, a ratio of the carbon concentration to the oxygen concentration in the at least one p-type semiconductor layer is more than or equal to 0.5 and is less than 1.

In an embodiment of the invention, carbon concentration of each semiconductor layer in the semiconductor light-emitting device is less than or equal to 5×10¹⁸ atoms/cm³.

In an embodiment of the invention, carbon concentration of the at least one p-type semiconductor layer in the semiconductor light-emitting device ranges from 2×10¹⁴ atoms/cm³ to 9×10¹⁷ atoms/cm³, and carbon concentration of the at least one n-type semiconductor layer ranges from 10¹⁴ atoms/cm³ to 10¹⁷ atoms/cm³.

In an embodiment of the invention, the at least one p-type semiconductor layer in the semiconductor light-emitting device is a plurality of p-type semiconductor layers, wherein carbon concentration of a p-type semiconductor layer closest to the light-emitting layer is more than carbon concentration of any other p-type semiconductor layer.

In an embodiment of the invention, light emitted from the light-emitting layer is light in an ultraviolet wavelength band.

In the semiconductor light-emitting device of the embodiments of the invention, since the ratio of carbon concentration to aluminum concentration in any one semiconductor layer containing aluminum in the semiconductor light-emitting device ranges from 10⁻⁴ to 10⁻², the semiconductor light-emitting device has a desirable ratio of carbon concentration to aluminum concentration, thereby effectively enhancing light-emitting efficiency of the semiconductor light-emitting device.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a semiconductor light-emitting device of an embodiment of the invention.

FIG. 2 is a schematic cross-sectional view of a semiconductor light-emitting device of another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

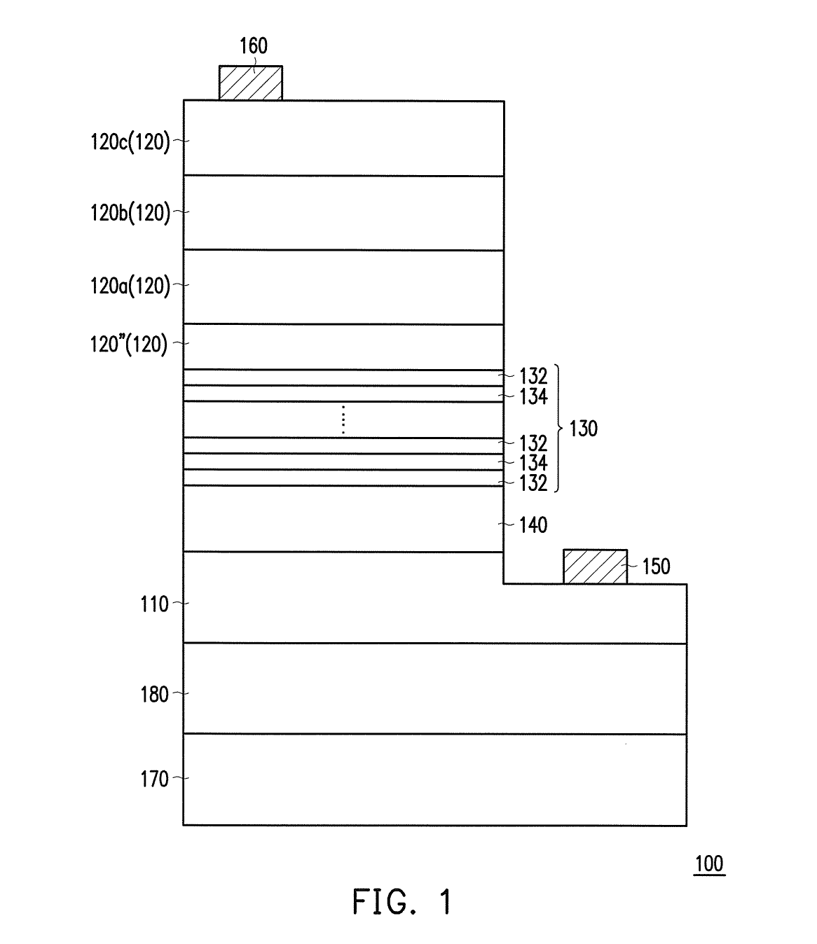

FIG. 1 is a schematic cross-sectional view of a semiconductor light-emitting device of an embodiment of the invention. Referring to FIG. 1, a semiconductor light-emitting device 100 of the embodiment includes at least one n-type semiconductor layer 110 (represented by one n-type semiconductor layer 110 as an example in FIG. 1), at least one p-type semiconductor layer 120 (represented by p-type semiconductor layers 120a, 120b, and 120c and an electron blocking layer 120″ as an example in FIG. 1), and a light-emitting layer 130. The light-emitting layer 130 is disposed between the p-type semiconductor layer 120 and the n-type semiconductor layer 110. In the embodiment, a material of the n-type semiconductor layer 110 is such as aluminum gallium nitride or gallium nitride, and a material of the p-type semiconductor layer 120 is such as aluminum gallium nitride or gallium nitride. In the embodiment, the light-emitting layer 130 includes a plurality of energy barrier layers 132 and a plurality of energy well layers 134 stacked alternately. That is, the light-emitting layer 130 is a multiple quantum well structure. In the embodiment, materials of the energy barrier layers 132 and the energy well layers 134 may be composed of different elements, or may be composed of the same elements but having different element proportions thereof, as long as an energy gap of the energy barrier layers 132 is more than an energy gap of the energy well layers 134. A material of the energy barrier layers 132 is such as gallium nitride, aluminum indium gallium nitride, or aluminum gallium nitride, and a material of the energy well layers 134 is such as gallium nitride, aluminum gallium nitride, indium gallium nitride, or aluminum indium gallium nitride.

In the embodiment, the semiconductor light-emitting device 100 further includes a strain relief layer 140 and the electron blocking layer 120″. The strain relief layer 140 is disposed between the n-type semiconductor layer 110 and the light-emitting layer 130 to release strain produced by the n-type semiconductor layer 110 in an epitaxial process. Thereby, the light-emitting layer 130 grown on the strain relief layer 140 can have better epitaxial quality. In the embodiment, the strain relief layer 140 is a superlattice layer formed from a plurality of aluminum gallium nitride layers and a plurality of aluminum indium gallium nitride layers stacked alternately, for example. However, the invention is not limited thereto. The electron blocking layer 120″ is disposed between the light-emitting layer 130 and the p-type semiconductor layers 120a, 120b, and 120c, so as to keep electrons as possible to recombine with electronic holes in the light-emitting layer 130 for light-emitting, thereby enhancing light-emitting efficiency. In the embodiment, a material of the electron blocking layer 120″ is aluminum gallium nitride, for example. However, the invention is not limited thereto.

In the embodiment, the semiconductor light-emitting device 100 further includes a substrate 170, a non-intentionally doped semiconductor layer 180, a first electrode 150, and a second electrode 160. The non-intentionally doped semiconductor layer 180 is formed on the substrate 170, and the n-type semiconductor layer 110, the strain relief layer 140, the light-emitting layer 130, the electron blocking layer 120″, and the p-type semiconductor layers 120a, 120b, and 120c are sequentially formed thereon. Additionally, the first electrode 150 is formed on the n-type semiconductor layer 110 and electrically connected to the n-type semiconductor layer 110. The second electrode 160 is formed on the p-type semiconductor layer 120 and electrically connected to the p-type semiconductor layer 120. In the embodiment, the substrate 170 is a sapphire substrate, for example. However, the invention is not limited thereto. Additionally, a material of the non-intentionally doped semiconductor layer 180 is non-intentionally doped aluminum gallium nitride, for example. However, the invention is not limited thereto.

In the embodiment, a ratio of carbon concentration to aluminum concentration in any one semiconductor layer (including the non-intentionally doped semiconductor layer 180, the n-type semiconductor layer 110, the strain relief layer 140, the light-emitting layer 130, the electron blocking layer 120″, and the p-type semiconductor layers 120a, 120b, and 120c, or plus any one semiconductor layer containing aluminum in other semiconductor layers not shown) containing aluminum in the semiconductor light-emitting device 100 ranges from 10⁻⁴ to 10⁻², wherein an unit of carbon concentration and aluminum concentration is atom/cm³, namely the number of atoms (e.g. carbon atom or aluminum atom) per cubic centimeter of volume.

In the semiconductor light-emitting device 100 of the embodiments of the invention, since the ratio of carbon concentration to aluminum concentration in any one semiconductor layer containing aluminum in the semiconductor light-emitting device 100 ranges from 10⁻⁴ to 10⁻², the semiconductor light-emitting device 100 has a desirable ratio of carbon concentration to aluminum concentration, thereby effectively enhancing light-emitting efficiency of the semiconductor light-emitting device 100.

In the embodiment, each semiconductor layer in the semiconductor light-emitting device 100 contains aluminum, and aluminum concentration of the each semiconductor layer ranges from 5×10¹⁹ atoms/cm³ to 5×10²⁰ atoms/cm³, for example. In the embodiment, carbon concentration is less than hydrogen concentration in the at least one p-type semiconductor layer 120 (i.e. the electron blocking layer 120″, and each of the p-type semiconductor layers 120a, 120b, and 120c, namely each p-type semiconductor layer 120 above the light-emitting layer 130). Additionally, in the embodiment, carbon concentration is less than oxygen concentration in the at least one p-type semiconductor layer 120. Particularly, in an embodiment, a ratio of the carbon concentration to the oxygen concentration in the at least one p-type semiconductor layer 120 is more than or equal to 0.5 and is less than 1. In other words, the carbon concentration of the each p-type semiconductor layer 120 above the light-emitting layer 130 is lower, which can be achieved by replacing trimethyl gallium (TMGa) with triethyl gallium (TEGa) of the material source of gallium in a metal organic chemical vapor deposition (MOCVD), or can be achieved by increasing the process temperature of an MOCVD.

In an embodiment, carbon concentration of each semiconductor layer in the semiconductor light-emitting device 100 is less than or equal to 5×10¹⁸ atoms/cm³, and preferably the carbon concentration of the each semiconductor layer in the semiconductor light-emitting device 100 is less than or equal to 5×10¹⁷ atoms/cm³. In an embodiment, carbon concentration of at least one p-type semiconductor layer 120 in the semiconductor light-emitting device 100 ranges from 2×10¹⁴ atoms/cm³ to 9×10¹⁷ atoms/cm³, and preferably the carbon concentration of at least one p-type semiconductor layer 120 in the semiconductor light-emitting device 100 ranges from 2×10¹⁵ atoms/cm³ to 5×10¹⁷ atoms/cm³; carbon concentration of the at least one n-type semiconductor layer 110 ranges from 10¹⁴ atoms/cm³ to 10¹⁷ atoms/cm³, and preferably the carbon concentration of the at least one n-type semiconductor layer 110 ranges from 10¹⁵ atoms/cm³ to 9×10¹⁶ atoms/cm³. In an embodiment, the at least one p-type semiconductor layer 120 in the semiconductor light-emitting device 100 is a plurality of p-type semiconductor layers 120, wherein carbon concentration of the p-type semiconductor layer 120 (e.g. the electron blocking layer 120″) closest to the light-emitting layer 130 is more than carbon concentration of any other p-type semiconductor layer 120 (e.g. the p-type semiconductor layer 120a, 120b, or 120c).

Additionally, in the embodiment, light emitted from the light-emitting layer 130 is light (e.g. light with wavelength less than 410 nm) in an ultraviolet wavelength band. The carbon concentration in the semiconductor light-emitting device 100 is lower, thus it is less likely to absorb UV light. This is because that carbon may produce defects in the epitaxial lattice, and the defects may absorb light with wavelength less than or equal to 410 nm. Therefore, the semiconductor light-emitting device 100 may have better light-emitting efficiency. However, in other embodiments, the light emitted from the light-emitting layer 130 may be blue light or green light.

The semiconductor light-emitting device 100 of the embodiment is a horizontal light-emitting diode, for example, wherein both the first electrode 150 and the second electrode 160 thereof are located at the same side of the semiconductor light-emitting device 100.

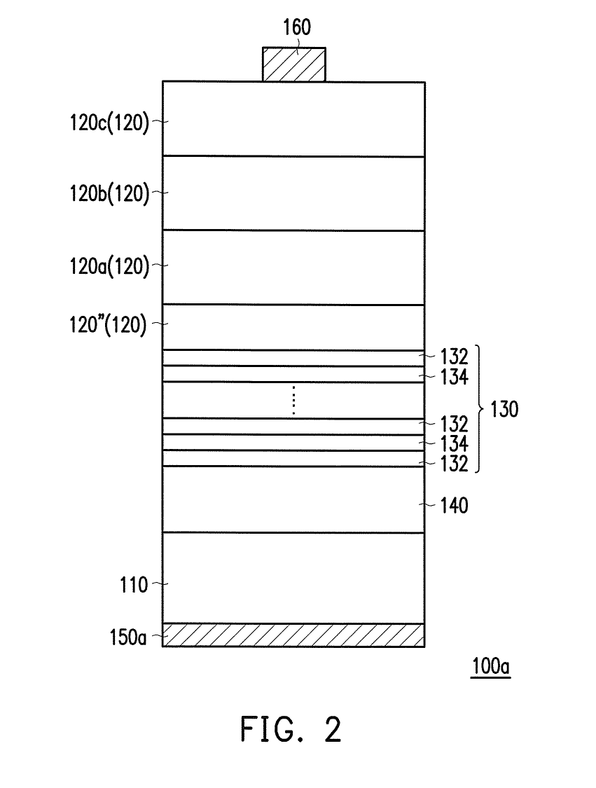

FIG. 2 is a schematic cross-sectional view of a semiconductor light-emitting device of another embodiment of the invention. Referring to FIG. 2, a semiconductor light-emitting device 100a of the embodiment is similar to the semiconductor light-emitting device 100 of FIG. 1, and the difference therebetween is that the semiconductor light-emitting device 100a of the embodiment is a vertical light-emitting diode, for example, wherein a first electrode 150a and the second electrode 160 thereof are located at opposite sides of the semiconductor light-emitting device 100a, respectively. Particularly, the first electrode 150a may be a conductive layer disposed under the n-type semiconductor layer 110 and electrically connected to the n-type semiconductor layer 110. In the embodiment, the first electrode 150a is directly disposed on a bottom surface of the n-type semiconductor layer 110. However, in other embodiments, the first electrode 150a and the n-type semiconductor layer 110 can be connected therebetween by a conductive substrate.

In summary, in the semiconductor light-emitting device of the embodiments of the invention, since the ratio of carbon concentration to aluminum concentration in any one semiconductor layer containing aluminum in the semiconductor light-emitting device ranges from 10⁻⁴ to 10⁻², the semiconductor light-emitting device has a desirable ratio of carbon concentration to aluminum concentration, thereby effectively enhancing light-emitting efficiency of the semiconductor light-emitting device.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

1. A semiconductor light-emitting device, comprising:
at least one n-type semiconductor layer;
at least one p-type semiconductor layer; and
a light-emitting layer disposed between the at least one p-type semiconductor layer and the at least one n-type semiconductor layer,
wherein a ratio of carbon concentration to aluminum concentration in any one semiconductor layer containing aluminum and carbon in the semiconductor light-emitting device ranges from 10⁻³ to 10⁻².

2. The semiconductor light-emitting device according to claim 1, wherein each semiconductor layer in the semiconductor light-emitting device contains aluminum.

3. The semiconductor light-emitting device according to claim 2, wherein aluminum concentration in each semiconductor layer ranges from 5×10¹⁹ atoms/cm³ to 5×10²⁰ atoms/cm³.

4. The semiconductor light-emitting device according to claim 2, wherein carbon concentration is less than hydrogen concentration in the at least one p-type semiconductor layer.

5. The semiconductor light-emitting device according to claim 2, wherein carbon concentration is less than oxygen concentration in the at least one p-type semiconductor layer.

6. The semiconductor light-emitting device according to claim 5, wherein a ratio of the carbon concentration to the oxygen concentration in the at least one p-type semiconductor layer is more than or equal to 0.5 and is less than 1.

7. The semiconductor light-emitting device according to claim 1, wherein carbon concentration of each semiconductor layer in the semiconductor light-emitting device is less than or equal to 5×10¹⁸ atoms/cm³.

8. The semiconductor light-emitting device according to claim 7, wherein carbon concentration of at least one p-type semiconductor layer in the semiconductor light-emitting device ranges from 2×10¹⁴ atoms/cm³ to 9×10¹⁷ atoms/cm³, and carbon concentration of at least one n-type semiconductor layer ranges from 10¹⁴ atoms/cm³ to 10¹⁷ atoms/cm³.

9. The semiconductor light-emitting device according to claim 1, wherein the at least one p-type semiconductor layer in the semiconductor light-emitting device is a plurality of p-type semiconductor layers, wherein carbon concentration of a p-type semiconductor layer closest to the light-emitting layer is more than carbon concentration of any other p-type semiconductor layer.

10. The semiconductor light-emitting device according to claim 1, wherein light emitted from the light-emitting layer is light in an ultraviolet wavelength band.
